(19) United States
(12) Patent Application Publication
(10) Pub. No.: US 2009/0065351 A1
(43) Pub. Date: Mar. 12, 2009

(54) Method and apparatus for deposition

(75) Inventor: Robert Nuss, Westland, MI (US)

Correspondence Address: James Wiegand, 2956 Waterview Drive, Rochester Hills, MI, 48309, US

(73) Assignee: Ovonyx, Inc.

(21) Appl. No.: 11/900,326

(22) Filed: Sep. 11, 2007

(51) Int. Cl. C23C 14/34

(52) U.S. Cl. 204/192.15; 204/192.12; 204/298.07; 204/298.12

(57) ABSTRACT

A deposition system supplies a continuous flow of process gases and sequentially selects among the flowing process gases for delivery to a reaction chamber. In the reaction chamber the delivered process gas acts as an ionizing species and thereby effects the deposition of a target substance upon a substrate. Gases not selected for delivery to the reaction chamber are swept away by a vacuum pump. By making a plurality of process gases continuously available, sequentially selecting among the available process gases, and pumping unused gases away before they enter the reaction chamber, such a system and method provides for continuous, sequential, uninterrupted deposition of a variety of substances, while maintaining desired flow rates and chamber pressures.

### CROSS-REFERENCE TO RELATED APPLICATIONS

Not Applicable

### FIELD OF INVENTION

This invention pertains to thin film deposition processes and systems. More particularly, this invention relates to the continuous deposition of thin films employing a plurality of process species.

### BACKGROUND OF THE INVENTION

Sputter deposition is a deposition process carried out within a reaction chamber in which atoms in a solid target material are ejected into the gas phase due to bombardment of the material by energetic ions. The gas-phase target material settles out and is then deposited on a substrate. Sputtering is commonly used for thin-film deposition, analytical techniques, and etching, for example. The material employed as a substrate in a sputtering process may be any supporting structure, including a semiconductor substrate, metals, alloys, glasses, polymers, ceramics, or other supportive materials.

Standard physical sputtering is driven by momentum exchange between accelerated ions and atoms in a target material due to collisions. The ions for the sputtering process are supplied either by a plasma that is induced in the sputtering equipment, or an ion or electron accelerator. In a plasma sputtering process, a variety of techniques may be employed to modify the plasma properties. In particular, the plasma's ion density is often manipulated to achieve the optimum sputtering conditions. Such plasma manipulation techniques include the use of radio frequency (RF) alternating current, the use of magnetic fields, and the application of a bias voltage to the target.

Standard physical sputtering employs an inert gas, such as argon, as the ionizing species. Reactive sputtering is a type of sputtering that employs reactive ions, such as oxygen or nitrogen, as the ionizing species. The reactive ions form oxides (oxygen) or nitrides (nitrogen) of the target material and these compound materials are deposited in layers on the substrate. Typically, reactive sputtering employs a mix of reactive and inert gases as ionizing species, with the percentage of reactive gases determining the composition of the reactively sputtered layers. Both standard physical sputtering and reactive sputtering can be carried out using plasma processes.

Most plasma processes involve control of the pressure within the reaction chamber, the electrical field characteristics, and the composition and proportional flow rates of individual gases into the plasma. Selection of these variables, in turn, affects the properties of a resulting thin film. Such properties can include the film's hardness, its adhesion to the substrate, its permeability to certain liquids or gases, optical characteristics, such as translucence and refractive index, and general composition. The property or properties of the resulting film that are important depend upon the purpose and application of the resulting product. For example, if a scratch resistant coating is being applied to glass, the film's hardness, adhesion to glass and degree of optical clarity are the most important properties. If, on the other hand, the film's oxygen permeability is the most critical feature, the process is controlled to emphasize that feature.

Deposition may be performed under manual control or automated closed-loop control. Manual control typically employs some measurement of plasma characteristics and the adjustment of controllable parameters, such as flow rate and pressure, to establish a plasma exhibiting characteristics that have empirically been found to produce the desired characteristics in a deposited film. For example, an operator may measure the electron temperature (Tₑ) of the plasma, a measure of the average electron energy in the plasma, by the use of available Langmuir (electrostatic) probe(s) positioned in the plasma. The operator then manually adjusts plasma variables until the average electron temperature corresponds to that which has been determined to be necessary for obtaining the desired film properties, or rate of deposition of the film. That determination may have been made, for example, through test depositions on an identical substrate material.

For large-scale, commercial operation, the sputtering process may be automated, using any of a variety of control methods. Automated closed loop control of sputtering systems is known and disclosed, for example, in U.S. Pat. No. 4,888,199 and U.S. Pat. No. 5,665,214, which are hereby incorporated by reference.

Regardless of whether a sputtering process is reactive or not or whether it is conducted under manual or automated closed loop control, the sputtering process must be halted in order to introduce different process gases into the process (ionizing species, whether reactive or inert, will be referred to herein as “process gases”). For example, in applications where multiple layers of different compositions are sputtered onto a target by employing different process gases, a layer would typically be sputtered within a reaction chamber using one of the gases. The system would then be shut down, a second process gas would be introduced into the chamber and a preferred flow rate and pressure established within the chamber, then a second layer would be sputtered onto the substrate. This process of establishing flow rates and pressures anew would be employed for each subsequent layer. In a conventional sputtering system, such an intermittent process is necessary to establish desired gas flow rates and reaction chamber pressures. Such a “stop and start” process is inordinately time consuming. Not only does such a process require the constant intervention of an operator, with concomitant expenditures of salary and benefits, as with any expensive piece of equipment, any process inefficiency, any “down time,” may have a dramatic effect on the commercial utility of the process. A system and method that eliminates the need for such constant intervention in a multi-layer, multi-gas, sputtering process would therefore be highly desirable.

### SUMMARY OF THE INVENTION

A system and method in accordance with the principles of the present invention supplies a continuous flow of process gases and sequentially selects among the flowing process gases for delivery to a reaction chamber. In the reaction chamber the delivered process gas acts as an ionizing species and thereby effects the deposition of a target substance upon a substrate. Gases not selected for delivery to the reaction chamber are swept away by one or more vacuum pumps. By making a plurality of process gases continuously available, sequentially selecting among the available process gases, and pumping away unused gases, such a system and method provides for continuous, sequential, uninterrupted deposition of a variety of substances, while maintaining desired flow rates and chamber pressures.

In an illustrative embodiment, a system and method in accordance with the principles of the present invention may supply argon gas to a plasma sputtering chamber that contains a chalcogenide target. A plasma is formed from the argon gas, and energetic ions in the argon plasma impinge the chalcogenide target to release chalcogenide material that deposits on a nearby substrate. When a desired thickness of the chalcogenide material has been deposited on the substrate, a system in accordance with the principles of the present invention may then, without interruption, switch from using argon to using a reactive gas or reactive gas/inert gas mixture as a sputtering gas. Because the flow of argon employed in the first deposition step is swept away before entering the chamber by a vent pump configured for the purpose, the flow rate of the argon gas may be maintained and a new gas may be routed into the chamber, without impact on the pressure within the reaction chamber. The reactive gas forms a plasma within the chamber, energetic ions within the reactive gas plasma eject chalcogenide material from the target and may further react with the ejected chalcogenide to deposit a layer of modified chalcogenide atop the layer of chalcogenide previously deposited.

The system may then switch, again without interruption, from using a first reactive gas (e.g. oxygen) to using a second reactive gas (e.g. nitrogen) as a sputtering gas to thereby deposit a layer of alternatively modified chalcogenide, or, alternatively, it may switch to argon as a source to thereby deposit a layer of chalcogenide. Use of oxygen as a reactive gas may lead to deposition of oxidized or oxygenated forms of chalcogenide materials. Use of nitrogen as a reactive gas may lead to deposition of nitrided or nitrogenated forms of chalcogenide materials. The sputtering steps may be repeated as desired to build a sequence of various material layers deposited atop the substrate. Although a system and method in accordance with the principles of the present invention may employ reactive (e.g. oxygen, nitrogen), or inert (e.g. argon) gases, or mixtures of gases as ionizing species; all gases supplied by such a system will be referred to herein as process gases. (Here I might recommend choosing other terminology. The sentence indicates that some of the process gases are reactive and some of the process gases are inert. In other words, we have reactive process gases and non-reactive process gases. Instead of “process gas”, can we simply say “process gas” or “supply gas”? Since I suspect that the term “process gas” will be widely used in what follows, I won't edit the term and will leave it to you to decide how to proceed.)

Employing a process gas source, a vacuum vent pump, and a reaction chamber to deliver gas flows to either the reaction chamber or vacuum vent pump, the process gas source sequentially supplies process gases from a plurality of process gases to the reaction chamber while maintaining desired gas flows and chamber pressure. The flow of one or more gases may be switched between the reaction chamber and the vacuum vent pump. With the vacuum vent pump maintaining substantially the same pressure as that of the reaction chamber, an established flow rate may be maintained when the flow is switched to the pump from the chamber. By maintaining this flow rate, gas at the identical flow rate will be available for switching back into the reaction chamber in a subsequent step.

In an illustrative embodiment of a sputter deposition system in accordance with the principles of the present invention, a valve system routes one or more of a plurality of available gases to either the reaction chamber or a vent pump. The valves may be operated independently and may be configured to close the path to the chamber entirely, thereby routing all available gases from the source to the vent pump. This configuration may be employed, for example, to establish desired flow rates of the individual gases while the reaction chamber is being prepared for operation.

During operation the valve system will typically open a path between one or more gas supplies and the reaction chamber. At the same time, the valve system will close the path(s) between the one or more selected gas supplies and the vent pump. Additionally, the valve system will manipulate paths for the one or more remaining, non-selected gases to block their entry to the chamber and to route their flows into the vent pump.

The plurality of gas supplies from the gas source may include different supplies providing the same gas at different flow rates. The supplies may also include gas mixtures of different compositions and flow rates. Additionally, the gas flow rates may be adjusted, for example, while gas supplies are being diverted to the vent pump and one or more other gases are being routed to the reaction chamber.

A system and method in accordance with the principles of the present invention provides for a continuous, sequential, supply of gases for a sputtering system. The gases may be selected from among a plurality of gases, each of which may be used as ionizing species in a sputtering system. Any of the gases may be substituted for another without shutting the system down in order to change the supply gas. The supply gases may include inert gases, such as argon, for example, reactive gases, such as oxygen or nitrogen, or various mixes of inert and reactive gases, for example.

### BRIEF DESCRIPTION OF THE DRAWINGS

FIG. 1 is a conceptual block diagram of a deposition system in accordance with the principles of the present invention;

FIG. 2 is a more detailed block diagram of a deposition system in accordance with the principles of the present invention;

FIG. 3 is a more detailed block diagram of a deposition system in accordance with the principles of the present invention;

FIG. 4 is a flow chart that depicts the major steps associated with a deposition process in accordance with the principles of the present invention;

FIG. 5 is a diagram of chalcogenide layers having different compositions deposited in a continuous deposition process in accordance with the principles of the present invention;

FIG. 6 is a diagram of chalcogenide layers having continuously-variable compositions deposited in a continuous deposition process in accordance with the principles of the present invention;

FIGS. 7A and 7B depict chalcogenide-based devices produced in a continuous deposition process in accordance with the principles of the present invention; and

FIG. 8 illustrates the components of a variety of systems that employ chalcogenide-based devices in accordance with the principles of the present invention.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, and electrical changes may be made without departing from the spirit or scope of the invention.

The term “substrate” used in the following description may include any supporting structure including, but not limited to, a semiconductor substrate that has an exposed substrate surface. The term semiconductor substrate may include, for example, silicon on insulator (SOI), silicon on sapphire (SOS), doped and undoped semiconductors, epitaxial layers of silicon supported by a base semiconductor foundation, and other semiconductor structures. When reference is made to substrate, semiconductor substrate, or wafer in the following description, previous process steps may have been used to form regions, junctions, circuits, and complex structures, including but not limited to a microprocessor or microcontroller, for example, in or over the base semiconductor or foundation. The substrate need not be semiconductor-based, but may be any support structure suitable for supporting an integrated circuit, including, but not limited to, metals, alloys, glasses, polymers, ceramics, solids, and other supportive materials as is known in the art.

The term “chalcogenide” is intended to include materials that comprise at least one element from group VIA (or group 16) of the periodic table. Group VIA elements (e.g., O, S, Se, Te, and Po) are also referred to as chalcogens. Accordingly, the scope of the invention is defined only by reference to the appended claims.

A wide range of chalcogenide compositions has been investigated in an effort to optimize the performance characteristics of chalcogenide devices. Chalcogenide materials generally include a chalcogen element and one or more chemical or structural modifying elements. The chalcogen element (e.g. Te, Se, S) is selected from column VI of the periodic table and the modifying elements may be selected, for example, from column III (e.g. Ga, Al, In), column IV (e.g. Si, Ge, Sn), or column V (e.g. P, As, Sb) of the periodic table. The role of modifying elements includes providing points of branching or cross-linking between chains comprising the chalcogen element. Column IV modifiers can function as tetracoordinate modifiers that include two coordinate positions within a chalcogenide chain and two coordinate positions that permit branching or crosslinking away from the chalcogenide chain. Column III and V modifiers can function as tricoordinate modifiers that include two coordinate positions within a chalcogenide chain and one coordinate position that permits branching or crosslinking away from the chalcogenide chain. Embodiments in accordance with the principles of the present invention may include binary, ternary, quaternary, and higher order chalcogenide alloys. Examples of chalcogenide materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. Chalcogenide materials may also be the resultant of a reactive sputtering process: a chalcogenide nitride, or oxide, for example and chalcogenide may be modified by an ion implantation or other process.

Early work in chalcogenide devices demonstrated electrical switching behavior in which switching from a resistive state to a conductive state was induced upon application of a voltage at or above the threshold voltage of the active chalcogenide material. This effect is the basis of the Ovonic Threshold Switch (OTS) and remains an important practical feature of chalcogenide materials. The OTS provides highly reproducible switching at ultrafast switching speeds for over 10¹³ cycles. Basic principles and operational features of the OTS are presented, for example, in U.S. Pat. Nos. 3,271,591; 5,543,737; 5,694,146; and 5,757,446; the disclosures of which are hereby incorporated by reference, as well as in several journal articles including “Reversible Electrical Switching Phenomena in Disordered Structures,” Physical Review Letters, vol. 21, p. 1450-1453 (1969) by S. R. Ovshinsky; “Amorphous Semiconductors for Switching, Memory, and Imaging Applications,” IEEE Transactions on Electron Devices, vol. ED-20, p. 91-105 (1973) by S. R. Ovshinsky and H. Fritzsche; the disclosures of which are hereby incorporated by reference.

Another important application of chalcogenide materials is in electrical and optical memory devices. One type of chalcogenide memory device utilizes the wide range of resistance values available for the material as the basis of memory operation. Each resistance value corresponds to a distinct structural state of the chalcogenide material and one or more of the states can be selected and used to define operation memory states. Chalcogenide materials exhibit a crystalline state, or phase, as well as an amorphous state, or phase. Different structural states of a chalcogenide material differ with respect to the relative proportions of crystalline and amorphous phase in a given volume or region of chalcogenide material. The range of resistance values is generally bounded by a set state and a reset state of the chalcogenide material. By convention, the set state is a low resistance structural state whose electrical properties are primarily controlled by the crystalline portion of the chalcogenide material and the reset state is a high resistance structural state whose electrical properties are primarily controlled by the amorphous portion of the chalcogenide-material.

Each memory state of a chalcogenide memory material corresponds to a distinct resistance value and each memory resistance value signifies unique informational content. Operationally, the chalcogenide material can be programmed into a particular memory state by providing an electric current pulse of an appropriate amplitude and duration to transform the chalcogenide material into the structural state having the desired resistance. By controlling the amount of energy provided to the chalcogenide material, it is possible to control the relative proportions of crystalline and amorphous phase regions within a volume of the material and to thereby control the structural (and corresponding memory) state of the chalcogenide material to store information.

Each memory state can be programmed by providing the current pulse characteristics of the state and each state can be identified, or “read”, in a non-destructive fashion by measuring the resistance. Programming among the different states is fully reversible and the memory devices can be written and read over a virtually unlimited number of cycles to provide robust and reliable operation. The variable resistance memory functionality of chalcogenide materials is currently being exploited in the OUM (Ovonic Universal (or Unified) Memory) devices that are beginning to appear on the market. Basic principles and operation of OUM type devices are presented, for example, in U.S. Pat. Nos. 6,859,390; 6,774,387; 6,687,153; and 6,314,014; the disclosures of which are incorporated by reference herein, as well as in several journal articles including, “Low Field Amorphous State Resistance and Threshold Voltage Drift in Chalcogenide Materials,” published in EE transactions on Electron Devices, vol. 51, p. 714-719 (2004) by Pirovana et al.; and “Morphing Memory,” published in IEEE Spectrum, vol. 167, p. 363-364 (2005) by Weiss.

The behavior (including switching, memory, and accumulation) and chemical compositions of chalcogenide materials have been described, for example, in the following U.S. Pat. Nos. 6,671,710; 6,714,954; 6,087,674; 5,166,758; 5,296,716; 5,536,947; 5,596,522; 5,825,046; 5,687,112; 5,912,839; and 3,530,441, the disclosures of which are hereby incorporated by reference. These references present proposed mechanisms that govern the behavior of chalcogenide materials. The references also describe the structural transformations from the crystalline state to the amorphous state (and vice versa) via a series of partially crystalline states in which the relative proportions of crystalline and amorphous regions vary during the operation of electrical and optical chalcogenide materials. Accordingly, the scope of the invention is defined only by reference to the appended claims.

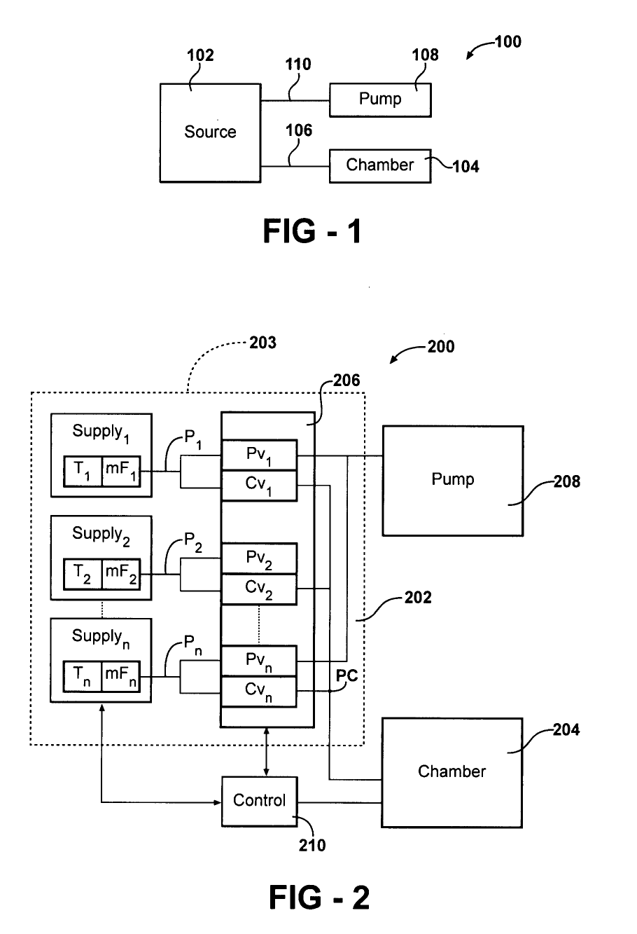

The conceptual block diagram of FIG. 1 illustrates basic components of a system 100 in accordance with the principles of the present invention. A gas source 102 supplies a continuous flow of process gases and sequentially selects among the flowing process gases for delivery to a reaction chamber 104 along a flow path 106. In the reaction chamber 104 the delivered process gas operates to deposit a substance of interest upon a substrate. The process gas may, for example, act as an ionizing species in a plasma sputtering chamber. Gases not selected for delivery to the reaction chamber 104 are swept away by one or more vacuum vent pump(s) 108 along a diversion path 10. By making a plurality of process gases continuously available and sequentially selecting among the available process gases, a system and method in accordance with the principles of the present invention provides for continuous, sequential, uninterrupted, deposition of a variety of substances.

For example, argon gas may be supplied along the flow path 106 to a plasma sputtering chamber that contains a chalcogenide target. The argon forms a plasma that ionizes the target and thereby deposits a layer of chalcogenide material on a substrate. When a desired thickness of the chalcogenide material has been deposited on the substrate, a system 100 in accordance with the principles of the present invention may then, without interruption, switch from using argon to oxygen (or an oxygen/inert gas mixture) as a process gas. In this subsequent step, the oxygen (or mixture) forms a plasma within the chamber, ionizes the chalcogenide target and reacts with the chalcogenide to deposit a layer of chalcogenide oxide or other oxidized chalcogenide atop the layer of chalcogenide previously deposited. The system 100 may then switch, again without interruption, from using oxygen to nitrogen as a process gas to thereby deposit a layer of chalcogenide nitride or other nitrided or nitrogenated chalcogenide. Alternatively, the system may switch to using argon as a process gas to thereby deposit another layer of chalcogenide. The sputtering steps may be repeated as desired to build a sequence of various material layers deposited atop the substrate. Although a system and method in accordance with the principles of the present invention may employ reactive (e.g. oxygen, nitrogen), inert (e.g. argon) gases, or mixtures of the inert and reactive gases as ionizing species; all gases supplied by such a system may be referred to herein generically as process gases.

The conceptual block diagram of FIG. 2 provides a somewhat more detailed view of the components of an illustrative embodiment of a system 200 in accordance with the principles of the present invention. A source 202 indicated by broken lines 203 includes a plurality of gas supplies, Supply1, Supply2, Supplyn (Supply1,2,n) coupled to a valve system 206 that includes valves PV1, PV2, and PVn (PV1,2,n) and CV1, CV2, and CVn (CV1,2,n). The gas supplies Supply1,2,n provide a variety of gases for operation in a reaction chamber 204 within which sputter deposition takes place. The gases provided by the supplies Supply1,2,n, may be chemically reactive gases, such as nitrogen or oxygen, or inert gases, such as argon, for example. The term “process gas” will be employed herein to refer to gases made available by the supplies Supply1,2,n to the reaction chamber 204, regardless of whether the gas itself is considered to be chemically reactive or inert.

Process gases are routed via the valve system 206 from the supplies Supply1,2,n to either a vacuum vent pump 208 or the reaction chamber 204. In accordance with the principles of the present invention, the valve system 206 includes a pump valve associated with each gas supply: PV1,2,n, and Supply1,2,n, respectively. The valve system 206 also includes a chamber valve associated with each gas supply: CV1,2,n, and Supply1,2,n, respectively. The pump valves PV1,2,n are operable to open or close (or constrict) a path between an associated gas supply Supply1,2,n and the vent pump 208. Similarly, the chamber valves CV1,2,n are operable to open or close (or constrict) a path between an associated gas supply Supply1,2,n and the chamber 204.

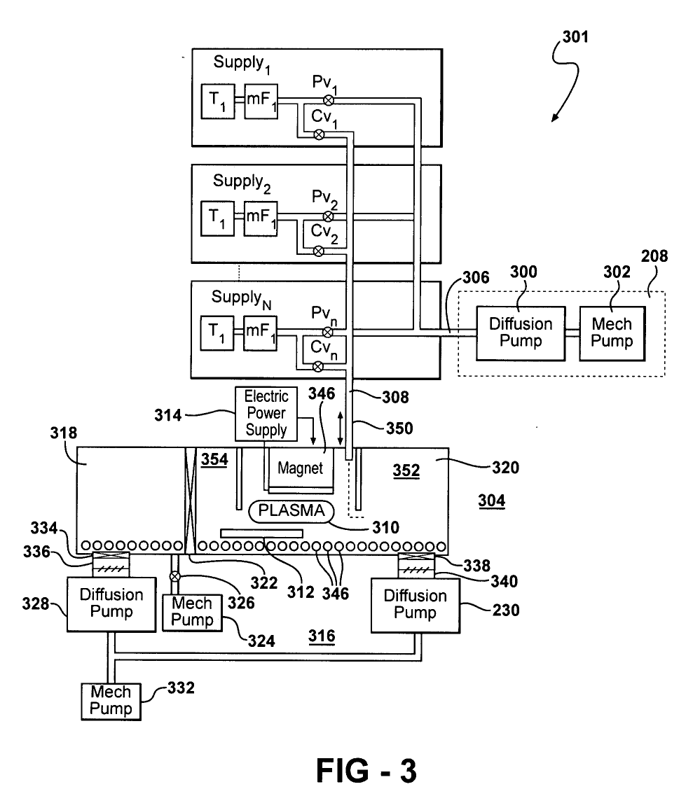

As will be described in greater detail in the discussion related to FIG. 3, a controller 210 monitors operation of the chamber 204 and exercises control over valves within the valve system 206 to supply process gases to the reaction chamber 204 according to the requirements of the process taking place within the reaction chamber 204. In closed-loop control embodiments, the controller 210 also exercises control over mass flow controllers within the gas supplies Supply1,2,n to similarly suit the requirements of the reaction taking place within the reaction chamber 204 and over operation of the valves within the valve system 206. Such control may be performed in response to feedback obtained from the chamber 204, for example.

In an illustrative embodiment, each gas supply Supply1,2,n includes a gas source, such as a tank, respectively labeled T1, T2, Tn (T1,2,n) and a mass flow controller, respectively labeled MFC1, MFC2, MFC3 (MFC1,2,n). Each tank contains a source gas under relatively high pressure and each mass flow controller MFC1,2,n is adjustable to precisely control the rate of flow from its associated tank T1,2,n. The gas output of each mass flow controller MFC1,2,n is routed to its associated pump PV1,2,n and chamber CV1,2,n valve through an associated pipe: P1,2,n. The outputs of the pump valves PV1,2,n are routed through a pump manifold PM to the pump 208. The outputs of the chamber valves CV1,2,n are routed through a chamber manifold CM to the chamber 204.

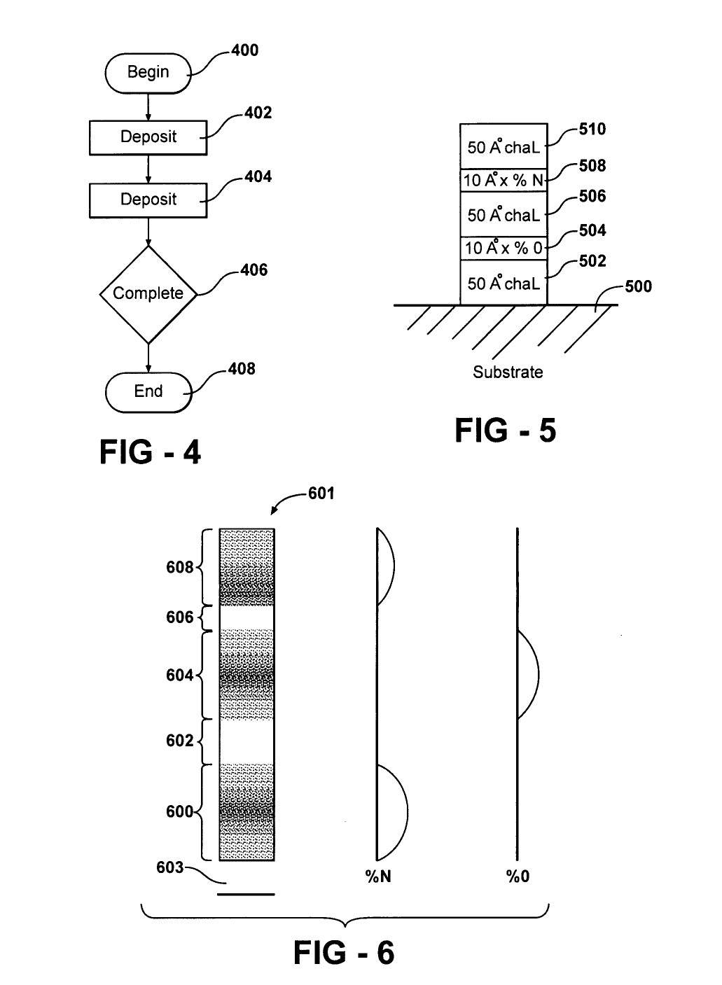

In operation, the valves PV1,2,n and CV1,2,n are manipulated, by the controller 210 for example, to provide a controlled flow of process gases to the chamber 204. Any combination of gases from any of the supplies Supply1,2,n, may be supplied to the chamber 204 by manipulation of the valve system 206 and the mass flow controllers MFC1,2,n. As previously described, the composition of the gases provided by the supplies Supply1,2,n may be of any type, including inert, reactive, or any combination of the two. Additionally, each supply may have its flow manipulated through its associated mass flow controller to provide a broad range of flow rates, including various flow rates for the same gas composition. As a result, a system in accordance with the principles of the present invention may provide a wide array of gas compositions and flow rates for reaction within the chamber 204. Gases from any of the supplies Supply1,2,n may be mixed within the chamber 204 by sequentially feeding the gases to be mixed into the chamber 204. As will be described in greater detail in the discussion related to FIGS. 4 and 5, a sequence of gases may be pulsed into the chamber 204 to deposit a sequence of layers having different compositions.

The schematic diagram of FIG. 3 provides a more detailed view of an illustrative embodiment of a sputtering system in accordance with the principles of the present invention. Process gases are available from Supplies 1 through n (Supply1,2,n) and are routed, as previously described, to a vent pump 208 which, in this illustrative embodiment, includes a cryogenic pump 300 and mechanical pump 302, or to a reaction chamber 304. Gases enter the vent pump 208 through a manifold 306. Gases selected for use in the chamber enter through a manifold 308. The vent pump 208 operates to direct all unused gases away from the chamber 304, to maintain pressure within the chamber 304 and to thereby enable continuous operation of the system 301.

Gases admitted to the reaction chamber 304 form a plasma 310. In operation a substrate 312 is placed within the chamber 304 for the purpose of depositing a thin film of material on it. The substrate 312 may be any vacuum compatible material, such as metal, glass, some plastics and coated substrates, as well as a substantially complete integrated circuit wafer. In an illustrative application of a system and method in accordance with the principles of the present invention, the substrate 312 may be a wafer containing a plurality of integrated circuit devices, such as microprocessors, for example. In such an embodiment, the layers to be deposited may include chalcogenide material and may be employed to form phase change random access memories (PRAM) or threshold switching devices atop the integrated circuit devices. A power supply 314 establishes an electric field and a pressure control system 316 establishes and maintains a low pressure environment within the chamber 304.

In an illustrative embodiment that employs closed loop control, a controller, such as controller 210 of FIG. 2, may be employed to receive status information from other components of the system and to send controlling commands to them. The reaction chamber 304 may be of an appropriate type to perform any of the sputtering, plasma-enhanced chemical vapor deposition (PECVD), plasma polymerization processes or other vacuum thin film deposition processes. A PECVD process will be discussed by way of example in the illustrative embodiment of FIG. 3.

The reaction chamber 304 is divided into a load lock compartment 318 and a process compartment 320 by an isolation slit valve 322. The pressure control system 316 includes a mechanical pump 324 connected to the load lock chamber 318 by a valve 326. The pressure control system also includes cryogenic pumps 328 and 330, and an associated mechanical pump 332. The cryogenic pump 328 is connected to the load lock chamber 318 through an isolation gate valve 334 and an adjustable baffle 336. Similarly, the cryogenic pump 330 is connected to the process chamber 320 through an isolation gate valve 338 and an adjustable baffle 340. The baffle 340 is controlled by a controller, such as controller 210 of FIG. 2, while a coating process is being carried out, in order to maintain the internal pressure at a desired value.

Closed loop control may be achieved using a variety of methods known in the art. For example, optical emissions from the plasma may be monitored and analyzed, as disclosed in U.S. Pat. No. 4,888,199 issued to Felts et al, closed loop voltage control is described in U.S. Pat. No. 5,108,569 issued to Gilbon et al, the intensity of a plasma's spectral line and a property of a finished coating are employed for closed loop control in a method described in U.S. Pat. No. 4,895,631 issued to Wirz et al, a deposition rate monitor and ellipsometer are employed for closed loop control in a method discussed in U.S. Pat. No. 5,665,214 issued to Iturralde, the disclosures of which are hereby incorporated by reference.

In this illustrative embodiment, a substrate to be coated is first loaded into the load lock compartment 318 with the valve 322 closed. The mechanical pump 324 then reduces the pressure within the compartment 318 substantially to the high vacuum region. The cryogenic pump 328 then reduces the pressure further, to the operating pressure. The operating pressure is typically in the neighborhood of 46 microns for a PECVD or plasma polymerization process and is achieved by flowing the process gases into the reaction chamber and throttling the cryogenic pump 330 by use of the baffle 340. During loading and unloading operations, the cryogenic pump 330 maintains the deposition chamber 320 at the operating pressure. Once the load lock chamber 318 is reduced to base pressure, the valve 322 is opened and the substrate 312 moved into the deposition chamber 320.

In this illustrative embodiment, the substrate 312 may be moved back and forth through a region where a plasma is formed. This is accomplished by a plurality of rollers 344, illustratively made of aluminum, with substrate supporting, electrical insulative O-ring spacers attached around outside surfaces. The rollers are driven by a motor source (not shown) to rotate about their axes at controllable speeds and thus move the substrate 312. A deposition process may involve passing the substrate 312 back and forth through the plasma a number of times in order that the thin film deposited on the top of the substrate 312 has a desired uniform thickness.

A magnetron is positioned within the chamber 320, formed of a magnetic structure 346 and a cathode 348. The power supply 314 has its output connected between the cathode 348 and a metallic body of the reaction chamber 320. The magnetron creates an appropriate combination of magnetic and electrical fields in order to create a plasma when the proper gases are introduced into the reaction chamber 320. The substrate 312 is maintained electrically isolated and is passed directly through the plasma region.

The gaseous components necessary for the plasma to form are introduced into the deposition chamber 320 by a manifold 308. The gas flows within the deposition chamber 320 generally from the supply tube to the cryogenic pump 330. In this illustrative embodiment, the gas is introduced on the side of the plasma region that is closest to the pump 330. A pair of baffles 352 and 354 on either side of the magnetron also helps to confine the gas flow to the plasma region 310.

The particular gas supply connected to the manifold 308 for a given coating operation depends on how many gases are being combined and their nature. In the example of FIG. 3, n separate supplies Supply1,2,n are delivered through individually controlled mass flow controllers MF1,2,n, respectively. As previously described, the supplies Supply1,2,n may provide inert gases, reactive gases, mixed gases, or combinations of gases.

The system controller may control the proportions of each gaseous component that is flowing through the manifold 308 and into the deposition chamber 320 by monitoring and manipulating the mass flow controllers MF1,2,n. In this illustrative embodiment, each of the mass flow controllers MF1,2,n, supplies the system controller with an electrical signal proportional to the flow rate of gas through it, and also responds to a signal from the system controller to adjust and control the flow rate.

In order to assure that the deposition rate is not limited by the amount of gas that is made available within the reaction chamber, the gas supply system and the pressure control system 316 need to be adequately sized. In particular, the pumps must be large enough to enable a sufficient flow of gases through the reaction chamber 304 to make available a steady supply of unreacted gases within the chamber for use in the deposition process. Similarly, the vent pump 208 must be of sufficient capacity to sweep away gases routed away from the reaction chamber 304 and to thereby prevent any buildup of gases or backpressure that may affect the supply of gases to the reaction chamber 304. At the same time, in order to take advantage of a given pumping capability in the pressure control system 316, the gas supply system must be adequately sized. The balance between the pumping ability and source gas supply is chosen to result in the desired operating pressure within the chamber 320, and to assure that the thin film deposition process is not limited in any way by a limited supply of a process gas component.

The flow chart of FIG. 4 illustrates the basic steps of chalcogenide deposition in accordance with the principles of the present invention. In the flow chart and this accompanying description it will be assumed that a substrate has been prepared and placed in a reaction chamber in a manner such as described in the discussion related to FIG. 3, for example. As previously noted, the substrate may be any supporting structure including, but not limited to, a semiconductor substrate that has an exposed substrate surface. Previous process steps may have been used to form regions, junctions, and complex structures, including but not limited to a microprocessor or microcontroller, for example, in or over the base semiconductor or foundation. The substrate need not be semiconductor-based, but may be any support structure suitable for supporting an integrated circuit, including, but not limited to, metals, alloys, glasses, polymers, ceramics, and other supportive materials as is known in the art. The illustrative process begins in step 400 and proceeds from there to step 402.

In step 402 a chalcogenide layer is deposited according to the process described in the discussion related to FIG. 3. The chalcogenide layer may be a binary, ternary, or quaternary type chalcogenide, for example. Such a material includes at least one of the chalcogen elements such as Te and/or Se, for example. Examples of chalcogenide materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. The chalcogenide layer deposited in step 402 may also be the resultant of a reactive sputtering process: a chalcogenide nitride, or oxide, for example. The desired thickness and stoichiometry of the layer to be deposited may be stored by a system controller such as previously described, for example.

During this step one or more gases from a gas source, such as the gas source 102 of FIG. 1 are introduced to a sputtering chamber to form a plasma which, in turn, ejects chalcogenide material from a target. Gases from the source not selected for introduction to the reaction chamber are swept away by a pump, as described, for example, in the discussion related to FIG. 3. The chalcogenide material ejected from the target forms a thin film on the substrate. When a reactive gas, such as oxygen or nitrogen is employed as the sputtering species, the species also reacts with the ejected chalcogenide to form a chalcogenide oxide or other oxidized or oxygenated chalcogenide, or a chalcogenide nitride or other nitrided or nitrogenated chalcogenide. The thickness and stoichiometry of the layer may be controlled, for example, using closed loop control methods as described in the discussions related to FIG. 3. When a suitable layer of material (chalcogenide, chalcogenide oxide, chalcogenide nitride, for example) has been deposited in step 402, the process proceeds to step 404.

In step 404, the process in accordance with the principles of the present invention proceeds to deposit another suitable layer of material (chalcogenide, chalcogenide oxide, chalcogenide nitride, for example). Because a system and method in accordance with the principles of the present invention sweeps away unused supply gases, supplies may be left “on” at a predetermined rate. For example, a gas supply and mass flow controller may combine to yield a stream of gas at a desired rate. That stream may be directed to the reaction chamber or, if that stream is not needed for the current deposition step, the stream may be directed to a pump, which disposes of the gas. In this manner, gas flow to the chamber may be shut off and, at the same time, a desired gas flow rate may be maintained for introduction to the chamber in a subsequent step. As previously described, a gas stream's rate of flow may also be modified, to suit a subsequent deposition step, for example, during the time that the stream is directed away from the reaction chamber. When a deposition layer is completed in step 404, the process proceeds to step 406 where the process determines whether all the desired chalcogenide layers have been deposited on the substrate. If all the layers have been deposited, the process proceeds to end in step 408. If additional layers are to be deposited, the process returns to step 402 and proceeds from there as previously described.

The sectional view of FIG. 5 provides a representative profile of chalcogenide layers deposited on a substrate employing a method and apparatus in accordance with the principles of the present invention. A substrate 500 may include a variety of structures and features, such as a microprocessor built using a CMOS process with additional interconnect lines for connection to layers deposited atop the microprocessor, as previously described. In this illustrative embodiment, a 50 Å layer of chalcogenide 502 has been deposited upon the substrate 500. Such a layer may be deposited, for example, by employing an inert gas such as argon as an ionizing species to sputter a chalcogenide target. In an illustrative embodiment, the pressure within the reaction chamber in which the chalcogenide is sputtered is maintained at approximately 2 millitorr and the temperature at 200° C., with a gas flow rate of 12.4 ccm. In this illustrative embodiment, layers of chalcogenide material are deposited at the rate, of approximately 60 Å to 80 Å per minute. Consequently, the 50 Å layer will be deposited in slightly less than a minute.

A 10 Å layer of chalcogenide oxide 504 has been deposited atop the chalcogenide layer 502. The percentage of oxide, (indicated as “X %” in the figure), may be determined, in part, by the proportion of oxygen (measured, for example, by partial pressure) introduced along with an inert gas into the chamber to operate as the ionizing species. A 50 Å layer of chalcogenide 506 has been deposited atop the oxide layer 504. A 10 Å layer of chalcogenide nitride 508 has been deposited atop the 50 Å layer of chalcogenide 506. The percentage of chalcogenide nitride, (indicated as “X %” in the figure), may be determined, in part, by the proportion of nitrogen introduced along with an inert gas into the chamber to operate as the ionizing species. In this illustrative embodiment, a 50 Å layer of chalcogenide 510 has been deposited atop the layer of chalcogenide nitride 508. Additional layers of chalcogenide, nitride (or nitrided or nitrogenated), and oxide (or oxidized or oxygenated) materials (not shown) may be added to the sequence of layers until a desired thickness is obtained. When complete, the total thickness of various layers of chalcogenide material may be on the order of 500 Å to 1000 Å. The composition of each layer, and the combination thereof, may be selected to produce a desired characteristic in the resultant stack of chalcogenide. For example, the resistivities of the various layers may be combined in such as way as to yield a desired bulk resistivity in the resultant stack.

The stack of FIG. 5 illustrates various combinations of chalcogenide, chalcogenide oxide, and chalcogenide nitride that may be deposited atop one another and atop a substrate by a system and method in accordance with principles of the present invention. The system and method are in no way limited by the compositions, thicknesses, or orders of deposition illustrated in the FIG. 5. As previously described, the deposition of the various layers may be performed continuously in accordance with the principles of the present invention. By using a pump to sweep away unused gases when those gas flows are not sent to the reaction chamber, gas flows may be introduced to the chamber and switched away from the chamber without disturbing the balance established within the chamber for proper reaction. That is, a desired reaction pressure may be maintained within the reaction chamber during the deposition of each layer of a multilayer sequence in a continuous process, regardless of which gas flow is directed to or away from the reaction chamber and without a need to stop or otherwise interrupt processing. The drawbacks of the intermittent processes known in the prior art for multilayer depositions are thereby avoided.

Although, in the illustrative embodiment of FIG. 5, each layer is depicted as having a single composition, each layer, or the entire resultant “stack,” or block, may be created with composition gradients. The result would be not so much layers as one or more continuously-variable composition regions. The conceptual graphs of FIG. 6 may be used to illustrate such a composition. In this illustrative embodiment, the block of chalcogenide material 601 includes continuously-variable composition region 600, region 604, and region 608. In each of these regions the shading of the region is meant to indicate the relative percentage of “dopant” substances that have been interacted with the chalcogenide during the deposition process. Corresponding graphical representations labeled % N and % O correlate relative composition percentages with the shading intensity of the continuously-variable composition regions. Region 600, for example, begins atop a substrate 603 with a continuously increasing percentage of nitrogen, reaches an inflection point at approximately the middle of the region and tapers to the pure chalcogenide composition of region 602. Similarly, region 604 begins with a continuously increasing percentage of oxygen, reaches an inflection point at approximately the middle of the region and tapers to the pure chalcogenide composition of region 606. Region 608 represents another region of continuously-variable composition that includes a varying amount of nitrogen.

In accordance with the principles of the present invention, the entire block 601 (exclusive of substrate 603), or any region within the block 601 may be of a continuously-variable composition. Such continuously-variable composition regions may be used, for example, to fine-tune the bulk properties of the block of chalcogenide material 601. Such properties may include, for example, resistivity, reflectivity, hardness, or index of refraction, for example. Because a system and method in accordance with the principles of the present invention includes a vent path and pump that sweeps away excess process gases the pressure within the reaction chamber may be maintained, even as the flow of process gases is adjusted to produce one or more continuously-variable composition chalcogenide regions. Automated control may be employed, for example, to operate a throttle valve associated with the vent pump to maintain pressure within the vent pump manifold (and, indirectly, within the reaction chamber) at a desired level. In this way desirable operating characteristics, such as temperature and pressure, within the reaction chamber may be maintained, even as the flow from a plurality of gas sources is introduced to the chamber (and, partially, to the vent pump) in a manner that would, without the presence of the vent pump, increase or decrease the pressure within the reaction chamber.

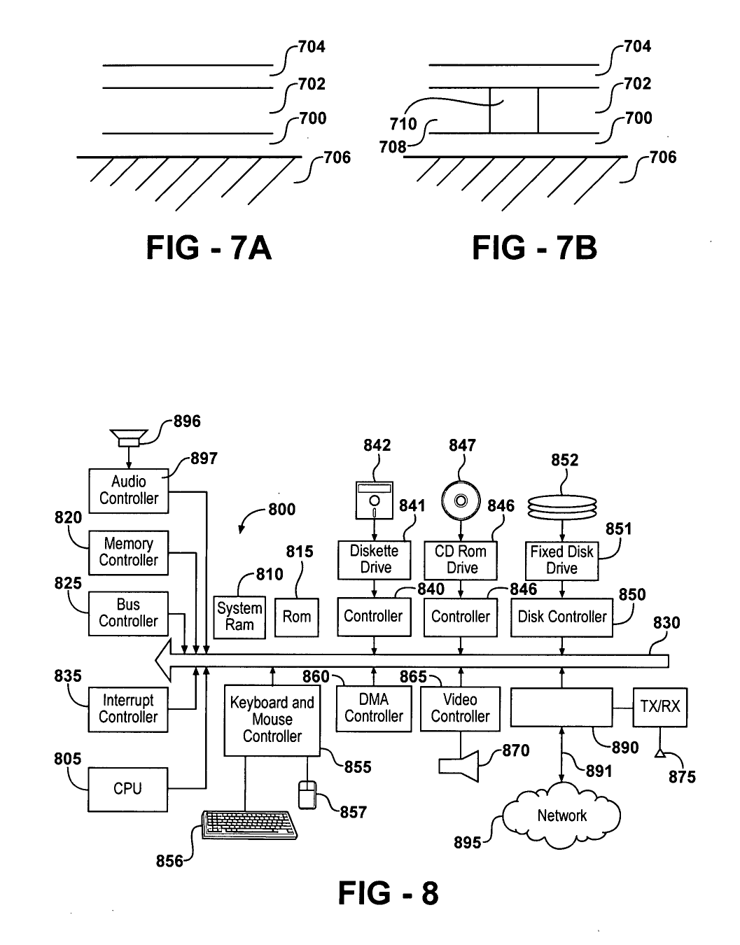

FIG. 7A provides an illustration of the basic structure of a chalcogenide electronic device in accordance with the principles of the present invention. A bottom electrode 700 and top electrode 704, formed of conductive material, sandwich a layer of chalcogenide material 702. In an illustrative embodiment, the electrodes are made of aluminum. In accordance with the principles of the present invention, all layers are deposited on top of a substrate 706 which, as previously described, may include a variety of structures and devices that have been formed in steps prior to the deposition of the chalcogenide layer 702. The composition of the chalcogenide layer 702 may be optimized for use as a threshold switch or memory cell. The chalcogenide-based threshold switches and memory cells may include various structures and complexities not illustrated here, but described, for example, in patents that were previously incorporated by reference herein.

A somewhat more complex chalcogenide-based memory cell is illustrated in FIG. 7B, where the substrate 706 lower electrode 700, chalcogenide 702 and upper electrode 704 are as previously described. In this illustrative embodiment insulating material 708 which may be SiO₂, for example, surrounds a plug of conductive material 710 that operates as a heater to induce localized phase changes in the chalcogenide layer 702. The heater may be composed of a metal or metal alloy, preferably resistive, such as tungsten, titanium, titanium nitride or other metal nitrides, titanium aluminum nitride, etc.

In these illustrative embodiments, the chalcogenide 702 of a chalcogenide-based electronics device, such as a memory or threshold switch, may be produced using the continuous deposition process previously described. Additionally, the chalcogenide layer 702 may be made up of several discrete layers of different composition, such as described in the discussion related to FIG. 5, or the layer may include one or more continuously-variable composition regions as described in the discussion related to FIG. 6.

The chalcogenide-based electronic device(s) described in the discussion related to the previous figures may be employed to particular advantage in a wide variety of systems. The schematic diagram of FIG. 8 will be employed to illustrate the devices' use in a few such systems. The schematic diagram of FIG. 8 includes many components and devices, some of which will be used for specific embodiments of a system in accordance with the principles of the present invention and others not. In other embodiments, other components and devices may be employed. The exemplary system of FIG. 8 is for descriptive purposes only. Although the description may refer to terms commonly used in describing particular computer, communications, tracking, and entertainment systems, the description and concepts equally apply to other systems, including systems having architectures dissimilar to that illustrated in FIG. 8. The electronic system 800, in various embodiments, may be implemented as, for example, a general purpose computer, a router, a large-scale data storage system, a portable computer, a personal digital assistant, a cellular telephone, an electronic entertainment device, such as a music or video playback device or electronic game, a microprocessor, a microcontroller, or a radio frequency identification device. Any or all of the components depicted in FIG. 8 may employ a chalcogenide electronic device, such as a chalcogenide-based nonvolatile memory or threshold switch, for example.

In an illustrative embodiment, the system 800 includes a central processing unit (CPU) 805, which may be implemented with a microprocessor, a random access memory (RAM) 810 for temporary storage of information, and a read only memory (ROM) 815 for permanent storage of information. A memory controller 820 is provided for controlling RAM 810. In accordance with the principles of the present invention, all of, or any portion of, any of the memory elements (e.g. RAM or ROM) may be implemented as chalcogenide-based nonvolatile memory.

In an illustrative embodiment, an electronic system 800 in accordance with the principles of the present invention is a microprocessor that operates as a CPU 805, in combination with embedded chalcogenide-based electronic nonvolatile memory that operates as RAM 810 and/or ROM815. In this illustrative example, the microprocessor/chalcogenide-nonvolatile memory combination may be standalone, or may operate with other components, such as those of FIG. 8 yet-to-be described.

In implementations within the scope of the invention, a bus 830 interconnects the components of the system 800. A bus controller 825 is provided for controlling bus 830. An interrupt controller 835 is used for receiving and processing various interrupt signals from the system components. Such components as the bus 830, bus controller 825, and interrupt controller 835 may be employed in a large-scale implementation of a system in accordance with the principles of the present invention, such as that of a standalone computer, a router, a portable computer, or a data storage system, for example.

Mass storage may be provided by diskette 842, CD ROM 847, or hard drive 852. Data and software may be exchanged with the system 800 via removable media such as diskette 842 and CD ROM 847. Diskette 842 is insertable into diskette drive 841 which is, in turn, connected to bus 830 by a controller 840. Similarly, CD ROM 847 is insertable into CD ROM drive 846 which is, in turn, connected to bus 830 by controller 845. Hard disc 852 is part of a fixed disc drive 851 which is connected to bus 830 by controller 850. Although conventional terms for storage devices (e.g., diskette) are being employed in this description of a system in accordance with the principles of the present invention, any or all of the storage devices may be implemented using chalcogenide-based nonvolatile memory in accordance with the principles of the present invention. Removable storage may be provided by a nonvolatile storage component, such as a thumb drive, that employs a chalcogenide-based nonvolatile memory in accordance with the principles of the present invention as the storage medium. Storage systems that employ chalcogenide-based nonvolatile memory as “plug and play” substitutes for conventional removable memory, such as disks or CD ROMs, for example, may emulate existing controllers to provide a transparent interface for controllers such as controllers 840, 845, and 8 50, for example.

User input to the system 800 may be provided by any of a number of devices. For example, a keyboard 856 and mouse 857 are connected to bus 830 by controller 855. An audio transducer 896, which may act as both a microphone and a speaker, is connected to bus 830 by audio controller 897, as illustrated. Other input devices, such as a pen and/or tabloid may be connected to bus 830 and an appropriate controller and software, as required, for use as input devices. DMA controller 860 is provided for performing direct memory access to RAM 810, which, as previously described, may be implemented using chalcogenide-based nonvolatile memory devices in accordance with the principles of the present invention. A visual display is generated by video controller 865 which controls display 870. The display 870 may be of any size or technology appropriate for a given application. In a cellular telephone or portable entertainment system embodiment, for example, the display 870 may include one or more relatively small (e.g. on the order of a few inches per side) LCD displays. In a large-scale data storage system, the display may implemented as large-scale multi-screen, liquid crystal displays (LCDs), or organic light emitting diodes (OLEDs), including quantum dot OLEDs, for example.

The system 800 may also include a communications adaptor 890 which allows the system to be interconnected to a local area network (LAN) or a wide area network (WAN), schematically illustrated by bus 891 and network 895. An input interface 899 operates in conjunction with an input device 893 to permit a user to send information, whether command and control, data, or other types of information, to the system 800. The input device and interface may be any of a number of common interface devices, such as a joystick, a touch-pad, a touch-screen, a speech-recognition device, or other known input device. In some embodiments of a system in accordance with the principles of the present invention, the adapter 890 may operate with transceiver 873 and antenna 875 to provide wireless communications, for example, in cellular telephone, RFID, and wifi computer implementations.

Operation of system 800 is generally controlled and coordinated by operating system software. The operating system controls allocation of system resources and performs tasks such as processing scheduling, memory management, networking, and I/O services, among things. In particular, an operating system resident in system memory and running on CPU 805 coordinates the operation of the other elements of the system 800.

In illustrative handheld electronic device embodiments of a system 800 in accordance with the principles of the present invention, such as a cellular telephone, a personal digital assistance, a digital organizer, a laptop computer, a handheld information device, a handheld entertainment device such as a device that plays music and/or video, small-scale input devices, such as keypads, function keys and soft keys, such as are known in the art, may be substituted for the controller 855, keyboard 856 and mouse 857, for example. Embodiments with a transmitter, recording capability, etc., may also include a microphone input (not shown).

In an illustrative RFID transponder implementation of a system 800 in accordance with the principles of the present invention, the antenna 875 may be configured to intercept an interrogation signal from a base station at a frequency F₁. The intercepted interrogation signal would then be conducted to a tuning circuit (not shown) that accepts signal F₁ and rejects all others. The signal then passes to the transceiver 873 where the modulations of the carrier F₁ comprising the interrogation signal are detected, amplified and shaped in known fashion. The detected interrogation signal then passes to a decoder and logic circuit which may be implemented as discrete logic in a low power application, for example, or as a microprocessor/memory combination as previously described. The interrogation signal modulations may define a code to either read data out from or write data into a chalcogenide-based nonvolatile memory in accordance with the principles of the present invention. In this illustrative embodiment, data read out from the memory is transferred to the transceiver 73 as an “answerback” signal on the antenna 875 at a second carrier frequency F₂. In passive RFID systems power is derived from the interrogating signal and memory such as provided by a chalcogenide-based nonvolatile memory in accordance with the principles of the present invention is particularly well suited to such use.

I claim:

1. An apparatus, comprising:
a gas source;
a pump; and
a reaction chamber, the gas source configured to controllably provide one or more gas flows from a selection of gases to the reaction chamber for use in a sputtering process, the pump configured to sweep away gases from the source that are not introduced to the reaction chamber.

2. The apparatus of claim 1 wherein the reaction chamber is configured as a deposition system.

3. The apparatus of claim 2 wherein the reaction chamber includes a chalcogenide target.

4. The apparatus of claim 3, wherein the source includes at least one inert gas supply.

5. The apparatus of claim 3, wherein the source includes at least one reactive gas supply.

6. The apparatus of claim 3, wherein the source includes at least one supply of a mixture of gases.

7. The apparatus of claim 6, wherein a supply includes a mixture of inert and reactive gases.

8. The apparatus of claim 3, wherein the source includes a plurality of supplies providing gas of the same composition at different flow rates.

9. The apparatus of claim 3 wherein the source includes valves that are configured to open gas flows from a gas supply to either the pump or reaction chamber, but not to both.

10. The apparatus of claim 3 wherein the chamber is configured to accept a substrate that includes integrated circuit components and to deposit a plurality of chalcogenide film layers upon the substrate.

11. The apparatus of claim 10 wherein at least one of the film layers is a chalcogenide oxide.

12. The apparatus of claim 10 wherein at least one of the film layers is a chalcogenide nitride.

13. The apparatus of claim 10 wherein the integrated circuit components form a microprocessor.

14. A process, comprising the steps:
supplying a flow of gas from a gas source; and
directing the flow of gas from the gas source to either a sputter reaction chamber or a pump.

15. The process of claim 14 further comprising the step of employing gas delivered to the reaction chamber as an ionizing species in a deposition process.

16. The process of claim 16, wherein the sputter deposition process employs a chalcogenide target.

17. The process of claim 16, wherein at least one inert gas is supplied to the reaction chamber.

18. The process of claim 16, wherein at least one reactive gas is supplied to the reaction chamber.

19. The process of claim 16, wherein at least one mixture of gases is supplied to the reaction chamber.

20. The process of claim 19, wherein at least one mixture of inert and reactive gases is supplied to the reaction chamber.

21. The process of claim 16, wherein a plurality of gas flows having the same composition but different flow rates are supplied to the reaction chamber.

22. The process of claim 16 wherein valves from a gas source are operated to supply gas flows from a gas supply to either the pump or reaction chamber, but not to both.

23. The process of claim 16 wherein a substrate that includes integrated circuit components is introduced to the reaction chamber and a plurality of chalcogenide film layers are deposited upon the substrate.

24. The process of claim 23 wherein at least one film layer of chalcogenide oxide is deposited.

25. The process of claim 23 wherein at least one film layer of chalcogenide nitride is deposited.

26. The process of claim 23 wherein the plurality of chalcogenide film layers are deposited upon a substrate that includes integrated circuit components that form a microprocessor.

27. The process of claim 16 wherein a region of chalcogenide having a continuously-variable composition is deposited.

28. A method of depositing a material comprising the steps of:
providing a reaction chamber, said reaction chamber including a substrate and a target;
introducing a first gas into said chamber;
forming a plasma from said first gas, said plasma comprising said first gas in an ionized state;
sputtering said target with said plasma to form a first layer on said substrate;
introducing a second gas into said chamber, the initiation of said introduction of said second gas step coinciding with the conclusion of said formation of first layer step;
ionizing said second gas, said ionized second gas combining with said plasma to form a modified plasma;
sputtering said target with said modified plasma to form a second layer over said first layer.

29. The method of claim 28, wherein said first gas is introduced continuously to said reactor during said step of sputtering said target with said plasma.

30. The method of claim 28, wherein said first gas is introduced continuously to said reactor during said step of sputtering said target with said modified plasma.

31. The method of claim 28, wherein said second gas is introduced continuously to said reactor during said step of sputtering said target with said modified plasma.

32. The method of claim 28, wherein said step of sputtering said target with said modified plasma is a reactive sputtering step.

33. The method of claim 28, wherein the composition of said second layer differs from the composition of said first layer.

34. The method of claim 28, wherein the composition of said first layer is homogeneous throughout the volume of said first layer.

35. The method of claim 34, wherein the composition of said second layer is homogeneous throughout the volume of said second layer.

36. The method of claim 35, wherein said second layer contacts said first layer.

37. The method of claim 35, wherein said second layer comprises an element contained in said second gas.

38. The method of claim 28, wherein the rate of introduction of said first gas is decreased upon said introduction of said second gas into said reaction chamber.

39. The method of claim 38, wherein the pressure within said reaction chamber remains substantially constant during introduction of said second gas into said reaction chamber.

40. The method of claim 28, wherein said sputtering said target with said modified plasma step continuously follows said sputtering said target with said plasma step.

41. The method of claim 28, wherein said target comprises a chalcogenide material.

42. The method of claim 28, wherein said first gas or said second gas comprises oxygen or nitrogen.

43. The method of claim 42, wherein said first gas or said second gas is oxygen or nitrogen.

44. The method of claim 28 wherein the gas pressure in said reaction chamber limited to no more than 20% change with the introduction of said second gas.

45. An apparatus comprising:
first and second electrodes; and
a chalcogenide layer disposed between and in electrical communication with the first and second electrodes, the chalcogenide layer having a plurality of sublayers of different composition formed in a continuous deposition process.

46. The apparatus of claim 45 wherein the chalcogenide is configured as a memory cell.

47. The apparatus of claim 45 wherein the chalcogenide is configured as a threshold switch.

48. The apparatus of claim 45 further comprising a substrate that includes a microprocessor, the microprocessor being in electrical communication with the electrodes, the combination thereby forming a microprocessor with embedded chalcogenide-based cells.

49. The apparatus of claim 48 further comprising input and output devices to form a computer with embedded chalcogenide-based cells.

50. The apparatus of claim 48 further comprising input and output devices to form an electronic entertainment device with embedded chalcogenide-based cells.

51. The apparatus of claim 48 further comprising an antenna and circuitry to form an electronic communication device with embedded chalcogenide-based cells.

52. The apparatus of claim 51 wherein the communication device is a cellular telephone with embedded chalcogenide-based cells.

53. The apparatus of claim 51 wherein the communications device is a computer having wireless communications capability and embedded chalcogenide-based cells.

54. The apparatus of claim 51 wherein the communications device is a radio a radio frequency identification tag with embedded chalcogenide-based cells.
